(19) United States
(12) Patent Application Publication
(10) Pub. No.: US 2016/0168378 A1
(43) Pub. Date: Jun. 16, 2016

(54) POLY(PHENYLENE ETHER) RESIN COMPOSITION, PREPREG, METAL-CLAD LAMINATE, AND PRINTED-WIRING BOARD

(71) Applicant: Panasonic Intellectual Property Management Co., Ltd., Osaka (JP)

(72) Inventors: HIROAKI UMEHARA, Osaka (JP); HIROHARU INOUE, Osaka (JP)

(21) Appl. No.: 14/956,358

(22) Filed: Dec. 1, 2015

(30) Foreign Application Priority Data
Dec. 16, 2014 (JP) 2014-253773

(51) Int. Cl. C08L 71/12; H05K 1/03

(52) U.S. Cl. CPC C08L 71/126; H05K 1/0353; C08L 2312/04

(57) ABSTRACT

A poly(phenylene ether) resin composition includes a modified poly(phenylene ether) copolymer, a polymer substance having a weight-average molecular weight larger than that of the modified poly(phenylene ether) copolymer, and a compound compatible with the modified poly(phenylene ether) copolymer. The modified poly(phenylene ether) copolymer is produced by modifying the phenolic hydroxyl group in a molecular terminal of a poly(phenylene ether) copolymer with a compound having a carbon-carbon unsaturated double bond. The polymer substance has a structure of at least one selected from a polystyrene framework, a polybutadiene framework, and a methacrylate framework. The polymer substance has a softening temperature not higher than 110° C. The compound compatible with the modified poly(phenylene ether) copolymer includes two or more carbon-carbon unsaturated double-bonds per molecule, and has a melting point not higher than 30° C.

### BACKGROUND

1. Field of the Disclosure

The present disclosure relates to poly(phenylene ether) resin compositions, prepreg, metal-clad laminates, and printed-wiring boards.

2. Description of the Related Art

In recent years, electrical equipment has progressed in high capacity for signals, which demands advanced dielectric characteristics, e.g. lower specific permittivity and lower dielectric loss tangent, required for high-speed communications in applications of semiconductor substrates and the like.

Poly(phenylene ether) (PPE) has good dielectric characteristics in terms of specific permittivity, dielectric loss tangent, etc. In particular, PPE is excellent in dielectric characteristics even in a high frequency band (high-frequency region) from MHz to GHz. Such characteristics allow PPE to be a candidate for high-frequency molding materials, for example. More specifically, PPE is attempted to be used for board materials and the like which is used as base materials of printed-wiring boards for electronic equipment used in a high-frequency band.

Previously, a resin composition using a modified poly(phenylene ether) compound has been disclosed in Japanese Patent Unexamined Publication (Translation of PCT Application) No. 2006-516297.

The publication describes a poly(phenylene ether) resin composition which includes a crosslinking curing agent and a poly(phenylene ether). Such poly(phenylene ether) has: a poly(phenylene ether) moiety in its molecular structure; p-ethenybenzyl and m-ethenybenzyl groups and the like in its molecular terminal; and a number-average molecular weight of 1,000 to 7,000.

### SUMMARY

The present disclosure provides a poly(phenylene ether) resin composition capable of reducing variations in thickness of an insulating layer, with excellent dielectric characteristics being held which is inherent in cured products of such a resin composition. Moreover, the present disclosure also provides prepreg using the poly(phenylene ether) resin composition, metal-clad laminates using the prepreg, and printed-wiring boards manufactured using the prepreg.

The poly(phenylene ether) resin composition of an aspect of the present disclosure includes a modified poly(phenylene ether) copolymer, a polymer substance having a weight-average molecular weight larger than that of the modified poly(phenylene ether) copolymer, a compound compatible with the modified poly(phenylene ether) copolymer. The modified poly(phenylene ether) copolymer is such that the phenolic hydroxyl group in a molecular terminal of a poly(phenylene ether) copolymer is modified with a compound that has a carbon-carbon unsaturated double bond. The polymer substance has a structure of at least one selected from a polystyrene framework, a polybutadiene framework, and a methacrylate framework. Moreover, the polymer substance has a softening temperature not higher than 110° C. The compound compatible with the modified poly(phenylene ether) copolymer has two or more carbon-carbon unsaturated double-bonds per molecule. The compound has a melting point not higher than 30° C.

The prepreg of another aspect of the present disclosure includes a substrate and the above-mentioned poly(phenylene ether) resin composition with which the substrate is impregnated.

The metal-clad laminate of yet another aspect of the present disclosure includes an insulating layer, which is a cured product of the above-mentioned prepreg, and metal foil disposed on the insulating layer.

Moreover, the printed-wiring board of still another aspect of the present disclosure includes an insulating layer, which is a cured product of the above-mentioned prepreg, and a conductive pattern disposed on the insulating layer.

In accordance with the present disclosure, the cured products of the poly(phenylene ether) resin composition and the prepreg using the resin composition exhibit excellent dielectric characteristics. Moreover, the metal-clad laminate fabricated by using the prepreg has high accuracy in thickness. In addition, the prepreg is so excellent in circuit filling properties that the printed-wiring board can be fabricated with high accuracy in thickness.

### BRIEF DESCRIPTION OF DRAWINGS

FIG. 1 is a schematic cross-sectional view of prepreg according to an embodiment of the present disclosure.

FIG. 2 is a schematic cross-sectional view of a laminate according to an embodiment of the present disclosure.

FIG. 3 is a schematic cross-sectional view of a metal-clad laminate according to an embodiment of the present disclosure.

FIG. 4 is a schematic cross-sectional view of a printed-wiring board according to an embodiment of the present disclosure.

### DETAILED DESCRIPTION OF THE PREFERRED EMBODIMENTS

Prior to descriptions of embodiments of the present disclosure, problems in conventional technologies will be briefly described. Use of a poly(phenylene ether) resin composition described in Japanese Patent Unexamined Publication (Translation of PCT Application) No. 2006-516297 allows a laminate that features dielectric characteristics and heat resistance. That is, the poly(phenylene ether) resin composition can be used to improve dielectric characteristics, for high-speed communications, of printed-wiring boards. However, in order to keep up with the rapidly increasing amount of information in recent high-frequency applications, such a printed-wiring board poses a further problem of signal delay time which is caused by variations in thickness of an insulating layer of the board. Accordingly, uniformity in thickness of the insulating layer of a printed wiring of the board has recently become a new problem to be solved.

Hereinafter, an embodiment of the present disclosure will be described. A poly(phenylene ether) resin composition according to the embodiment of the present disclosure includes components (A), (B), and (C). Component (A) is a modified poly(phenylene ether) copolymer. Component (B) is a polymer substance which has a weight-average molecular weight (Mw) larger than the Mw of the modified poly(phenylene ether) copolymer. Component (C) is a compound which is compatible with the modified poly(phenylene ether) copolymer. In the modified poly(phenylene ether) copolymer, the phenolic hydroxyl group of the molecule terminal of a poly(phenylene ether) copolymer is modified with a compound which has a carbon-carbon unsaturated double bond. The polymer substance has at least one structure selected from a polystyrene framework, a polybutadiene framework, and a methacrylate framework. The polymer substance has a softening temperature of not higher than 110° C. The compound compatible with the modified poly(phenylene ether) copolymer has two or more carbon-carbon unsaturated double bonds per molecule. The compound has a melting point of not higher than 30° C.

Cured products of such a poly(phenylene ether) resin composition exhibit excellent dielectric characteristics. The resin composition can be used to manufacture metal-clad laminates and printed-wiring boards with higher accuracy in their thicknesses.

Hereinafter, a specific description will be made regarding each component of the poly(phenylene ether) resin composition according to the embodiment.

The modified poly(phenylene ether), component (A), is not limited to specific one, but may be any kind of modified poly(phenylene ether) as long as it has undergone modification of its terminal with a substituent group which includes a carbon-carbon unsaturated double bond.

Such a substituent group including the carbon-carbon unsaturated double bond is not limited to specific one, but may be the substituent group expressed by the following Formula (1).

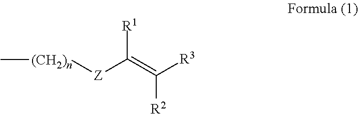

In Formula (1), “n” is an integer of not smaller than 0 (zero) and not larger than 10. “Z” is an arylene group. When n is 0 (zero), “Z” may be a carbonyl group. Each of R¹ to R³ is independently a hydrogen atom or an alkyl group. Note that, when n is 0 (zero) in Formula (1), it means that “Z” is bonded directly to the terminal of the poly(phenylene ether).

The arylene group and carbonyl group both expressed by “Z” include: a monocyclic aromatic group such as a phenylene group, and a polycyclic aromatic group such as a naphthalene ring, for example. “Z” also includes a derivative in which the hydrogen atom bonded to the aromatic group is substituted with a functional group including: an alkenyl group, an alkynyl group, a formyl group, an alkyl-carbonyl group, an alkenyl-carbonyl group, and alkynyl-carbonyl group.

A preferable specific example of the functional group expressed by Formula (1) is a functional group including a vinylbenzyl group. Specifically, the functional group may include at least one selected from the substituent groups expressed by the following Formulas (2) and (3).

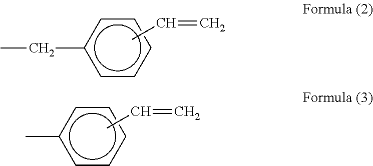

In the modified poly(phenylene ether) as component (A), a methacrylate group may be used as another substituent group which has carbon-carbon unsaturated double bonds and is introduced via terminal modification. Such a methacrylate group has a structure expressed by the following Formula (4), for example.

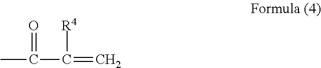

In Formula (4), R¹ represents a hydrogen atom or an alkyl group.

The weight-average molecular weight (Mw) of the modified poly(phenylene ether), component (A), is not limited to a specific value. However, the Mw is preferably not smaller than 500 and not larger than 5,000, more preferably not smaller than 800 and not larger than 4,000, and yet more preferably not smaller than 1,000 and not larger than 3,000. Note that the Mw may be a measured value determined by a common method of measuring molecular weight. Specifically, gel permeation chromatography (GPC) can be used to determine the value, for example.

Such a range of Mw of the modified poly(phenylene ether) described above allows the cured product thereof to reliably exhibit excellent adhesion and heat resistance as well as dielectric characteristics which are unique to the poly(phenylene ether).

For conventional poly(phenylene ether), if its Mw is in such a range, the molecular weight is relatively so low for the conventional poly(phenylene ether) that the cured product thereof unfavorably tend to degrade in heat resistance. In contrast, it is considered that the cured product of the modified poly(phenylene ether) compound, component (A), exhibit sufficiently high heat resistance and adhesion. This is because component (A) has one or more unsaturated double bonds in its terminal.

Then, a description will be made regarding the average number of the substituent groups per molecule of the modified poly(phenylene ether), component (A), with the substituent groups having a carbon-carbon unsaturated double bond and being bonded to the terminal of the molecule. The average number (the number of the terminal substituent groups) is preferably not smaller than 1.5 and not larger than 3, more preferably not smaller than 1.7 and not larger than 2.7, and yet more preferably not smaller than 1.8 and not larger than 2.5. The excessively smaller number of the substituent groups tends to cause the cured product to exhibit insufficient heat resistance. Difficulty in formation of crosslinking points is considered to be responsible for this. On the other hand, the excessively larger number of the substituent groups possibly causes faults due to excessively high reactivity. This causes degradation, for example, in shelf life and flowability of the poly(phenylene ether) resin composition.

As the number of the terminal substituent groups of the modified poly(phenylene ether) may be the value, an average of the number of the substituent groups per molecule of all of the modified poly(phenylene ether) present in one mole of the modified poly(phenylene ether) can be used. The number of the terminal substituent groups can be determined, for example, by measuring the number of hydroxyl groups that remains in the modified poly(phenylene ether) after modification, and then calculating the decrease in the number of hydroxyl groups from the poly(phenylene ether) prior to the modification. This decrease in the number of the hydroxyl groups from the poly(phenylene ether) prior to the modification is equal to the number of the terminal substituent groups. The number of the hydroxyl groups remaining in the modified poly(phenylene ether) can be determined by adding a quaternary ammonium salt (tetraethylammonium hydroxide) associative with hydroxyl groups to a solution of the modified poly(phenylene ether), and then measuring UV-absorbance of the mixed solution.

Moreover, the intrinsic viscosity of the modified poly(phenylene ether), component (A), is preferably not smaller than 0.03 dl/g and not larger than 0.12 dl/g, more preferably not smaller than 0.04 dl/g and not larger than 0.11 dl/g, and yet more preferably not smaller than 0.06 dl/g and not larger than 0.095 dl/g. The excessively low intrinsic viscosity tends to result from low molecular weight, which results in an increase in specific permittivity and dielectric loss tangent of the cured product, leading to the tendency for the cured product to fail to achieve low dielectric performance. On the other hand, the excessively high intrinsic viscosity tends to cause insufficient flowability and reduced formability due to high viscosity when the cured product is formed. Accordingly, when the modified poly(phenylene ether) has the intrinsic viscosity within the range described above, its cured product has excellent heat resistance, adhesion, etc.

Note that the intrinsic viscosity as referred herein is intrinsic viscosity measured using methylene chloride at a temperature of 25° C. More specifically, for example, a solution of 0.18 g/45 ml methylene chloride in water (solution temperature of 25° C.) is measured with a capillary viscometer. The capillary viscometer may be an AVS500 Visco System manufactured by SCHOTT Instruments GmbH, for example.

Moreover, for the modified poly(phenylene ether) of component (A), the content of the components with molecular weights not smaller than 13,000 is preferably 5 mass % or less. That is, the molecular weight distribution of the modified poly(phenylene ether) is preferably relatively narrow. In particular, for the modified poly(phenylene ether), the content of the components with molecular weights not smaller than 13000 is preferably small. The components with such large molecular weights may be absent. That is, the lower limit of the content range of the components with molecular weights not smaller than 13000 may be 0 (zero) mass %. Moreover, for the modified poly(phenylene ether), the content of the components with a molecular weight not smaller than 13000 may be preferably in a range from 0 (zero) mass % to 5 mass %, inclusive, and more preferably from 0 (zero) mass % to 3 mass %, inclusive. In this way, when the modified poly(phenylene ether) shows the small content of the components with a large molecular weight and the narrow molecular-weight distribution, the modified poly(phenylene ether) exhibits higher reactivity dedicating to the curing reaction and higher flowability.

Note that the content of the components with the large molecular weight can be determined by measuring the molecular weight distribution by GPC, followed by calculation based on the measured molecular weight distribution. Specifically, the content is calculated from the ratio of a peak area in the curve of the molecular weight distribution obtained by GPC.

Moreover, the modified poly(phenylene ether), component (A), preferably includes a poly(phenylene ether) chain in its molecule. For example, the molecule includes repetitive units expressed by the following Formula (5).

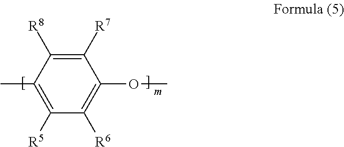

In Formula (5), “m” is an integer of not smaller than 1 and not larger than 50. R⁵ to R⁸ are independent of each other. That is, R⁵ to R⁸ may be the same group or, alternatively, different groups from each other. Each of R⁵ to R⁸ is independently a hydrogen atom, an alkyl group, an alkenyl group, an alkynyl group, a formyl group, an alkyl-carbonyl group, an alkenyl-carbonyl group, or an alkynyl-carbonyl group, respectively. Among them, the hydrogen atom or the alkyl group is preferably adopted.

Specifically, the functional groups listed above as R⁵ to R⁸ include the following structures.

The alkyl group is not limited to a specific one. For example, an alkyl group including 1 to 18 carbon atoms is preferably adopted, and an alkyl group including 1 to 10 carbon atoms is more preferable. Specifically, such an alkyl group includes methyl group, ethyl group, propyl group, hexyl group, and decyl group, for example.

The alkenyl group is not limited to a specific one. For example, an alkenyl group including 2 to 18 carbon atoms is preferably adopted, and an alkenyl group including 2 to 10 carbon atoms is more preferable. Specifically, such an alkenyl group includes vinyl group, allyl group, and 3-butenyl group, for example.

The alkynyl group is not limited to a specific one. For example, an alkynyl group including 2 to 18 carbon atoms is preferably adopted, and an alkynyl group including 2 to 10 carbon atoms is more preferable. Specifically, such an alkynyl group includes ethynyl group, and prop-2-yn-1-yl group (propargyl group), for example.

The alkyl-carbonyl group is not limited to a specific one as long as it is a carbonyl group of which terminal is substituted with an alkyl group. For example, an alkyl-carbonyl group including 2 to 18 carbon atoms is preferably adopted, and an alkyl-carbonyl group including 2 to 10 carbon atoms is more preferable. Specifically, such an alkyl-carbonyl group includes acetyl group, propionyl group, butylyl group, isobutyryl group, pivaloyl group, hexanoyl group, octanoyl group, and cyclohexyl-carbonyl group, for example.

The alkenyl-carbonyl group is not limited to a specific one as long as it is a carbonyl group of which terminal is substituted with an alkenyl group. For example, an alkenyl-carbonyl group including 3 to 18 carbon atoms is preferably adopted, and an alkenyl-carbonyl group including 3 to 10 carbon atoms is more preferable. Specifically, such an alkyl-carbonyl group includes acryloyl group, methacryloyl group, and crotonoyl group, for example.

The alkynyl-carbonyl group is not limited to a specific one as long as it is a carbonyl group of which terminal is substituted with an alkynyl group. For example, an alkynyl-carbonyl group including 3 to 18 carbon atoms is preferably adopted, and an alkynyl-carbonyl group including 3 to 10 carbon atoms is more preferable. Specifically, such an alkynyl-carbonyl group includes propioloyl group, for example.

Moreover, in cases where the modified poly(phenylene ether) includes, in its molecular, the repetitive units expressed by Formula (5), “in” is preferably a numeric value with which the Mw of the modified poly(phenylene ether) is within the range described above. Specifically, “m” is preferably 1 to 50.

The synthesis method of the modified poly(phenylene ether), component (A), is not limited to a specific one as long as the modified poly(phenylene ether) can be synthesized, with structure in which the terminal of the poly(phenylene ether) is substituted with a substituent group that has a carbon-carbon unsaturated double bond. Specifically, for example, the synthesis method includes causing poly(phenylene ether) to react with a compound as shown by the following Formula (6). In the poly(phenylene ether), the hydrogen atom of a phenolic hydroxyl group of the terminal thereof is substituted with an alkali metal atom such as sodium and potassium one in advance.

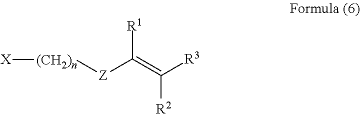

In Formula (6), as in the case of Formula (1), “n” is an integer in a range from 0 (zero) to 10, inclusive. “Z” is an arylene group. Each of R¹ to R³ is independently a hydrogen atom or an alkyl group. “X” is a halogen atom, specifically one of chlorine atom, bromine atom, iodine atom, and fluorine atom. Among them, chlorine atom is preferably adopted.

Moreover, the compound expressed by Formula (6) is not limited to a specific one; however, p-chloromethylstyrene or m-chloromethylstyrene may be preferably adopted.

Furthermore, for the compound expressed by Formula (6), the compound exemplified above may be solely used or, alternatively, two or more different compounds exemplified above may be combined and used.

The poly(phenylene ether) serving as the starting material is not limited to a specific one as long as it eventually allows the synthesis of the predetermined modified poly(phenylene ether). Specifically, examples of such a poly(phenylene ether) include a poly(arylene ether) copolymer, and a poly(phenylene ether) as a principal component. The poly(arylene ether) copolymer is synthesized from 2, 6-dimethylphenol and at least one of a bifunctional phenol and a trifunctional phenol. One example of the poly(phenylene ether) is poly(2, 6-dimethyl-1,4-phenylene oxide). More specifically, such a poly(phenylene ether) has the structure expressed by the following Formula (7), for example.

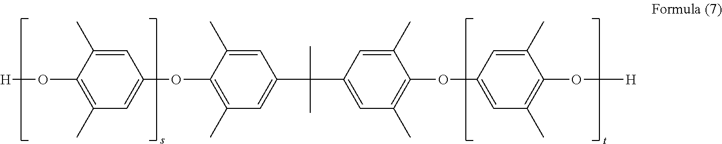

In Formula (7), the sum of “s” and “t” is preferably an integer in a range from 1 to 30, inclusive; “s” is preferably an integer in a range from 0 (zero) to 20, inclusive; “t” is preferably an integer in a range from 0 (zero) to 20, inclusive.

The synthesis method of the modified poly(phenylene ether) includes the method described above. Specifically, the poly(phenylene ether) described above and the compound expressed by Formula (6) are dissolved in a solvent, then are stirred. In this process, the poly(phenylene ether) reacts with the compound expressed by Formula (6) to form the modified poly(phenylene ether) to be used in the embodiment.

This reaction is preferably carried out in the presence of an alkali metal hydroxide. The alkali metal hydroxide is considered to enhance the reaction preferably.

The alkali metal hydroxide is not limited to a specific one as long as it can serve as a dehalogenation agent. Examples of such an alkali metal hydroxide include sodium hydroxide. Incidentally, the alkali metal hydroxide is usually used in a state of an aqueous solution. Specifically an aqueous solution of sodium hydroxide is used.

Reaction conditions, e.g. reaction time and reaction temperature, can be changed depending on the compound expressed by Formula (6) and the like; therefore, the conditions are not limited to specific ones as long as they allow favorable progress of the reaction described above. Specifically, the reaction temperature is preferably from room temperature to 100° C. and more specifically from 30° C. to 100° C. The reaction time is preferably from 0.5 hour to 20 hours and more specifically from 0.5 hour to 10 hours.

The solvent used for the reaction is not limited to a specific one provided that it can dissolve the poly(phenylene ether) and the compound expressed by Formula (6) and that it does not hinder the reaction of the poly(phenylene ether) with the compound expressed by Formula (6). Specifically, examples of such a solvent include toluene.

Furthermore, the reaction described above is preferably carried out in a state where a phase-transfer catalyst is present together with the alkali metal hydroxide. That is, the reaction described above is preferably carried out in the presence of the alkali metal hydroxide and the phase-transfer catalyst. Such a presence is thought to enhance the above-described reaction more favorably.

The phase-transfer catalyst is not limited to a specific one; however, examples of the catalyst include a quaternary ammonium salt or the like such as tetra-n-butylammonium bromide.

The poly(phenylene ether) resin composition according to the embodiment preferably contains the modified poly(phenylene ether) that is prepared in the manner described above.

Next, a description will be made regarding component (B) used in the embodiment which is the polymer substance having larger Mw than that of component (A), i.e. the modified poly(phenylene ether) copolymer. The polymer substance has at least one structure selected from (I) a polystyrene framework, (II) a polybutadiene framework, and (III) a methacrylate framework. The polymer substance has a softening temperature of not higher than 110° C.

The polymer substance as component (B) is not limited to a specific one as long as it has the Mw larger than that of the modified poly(phenylene ether) copolymer, i.e. component (A). However, the Mw of the polymer substance is preferably in a range from 10,000 to 900,000, inclusive. Such a range of the Mw allows increased accuracy in thickness of the metal-clad laminate or the like that is manufactured using the poly(phenylene ether) resin composition according to the embodiment. On the other hand, if the Mw of the polymer substance exceeds 900,000, it may result in degraded impregnation properties of a varnish into a substrate when prepreg is manufactured, which is attributed to an increase in viscosity of the varnish of the resin composition.

Moreover, the polymer substance, component (B), has at least one structure selected from (I) a polystyrene framework, (II) a polybutadiene framework, and (III) a methacrylate framework. This configuration allows decreased variations in thickness of the insulating layer of the metal-clad laminate or the like manufactured including the resin composition without a large decrease in dielectric characteristics of the cured product of the resin composition.

The polymer substance, component (B), has a softening temperature of not higher than 110° C. Use of the polymer substance having such a low softening temperature results in a lowered softening temperature of the resin composition. This allows a reduced melt viscosity of the resin composition during heat molding, thereby making secondary molding of the prepreg easier, and thus leading to improved circuit filling properties. Note that the softening temperature referred in the embodiment can be measured as a Vicat softening temperature in accordance win Japanese Industrial Standard JIS K7206 which corresponds to ISO 306 1994.

Specifically, examples of the polymer substance, component (B), include a polystyrene, a polybutadiene, a butadiene-styrene copolymer, and an acrylic copolymer.

Next, a description will be made regarding the compound, serving as component (C), that has two or more carbon-carbon unsaturated double bonds per molecule and a melting point of not higher than 30° C., and is compatible with component (A).

The compound of component (C) is not limited to a specific one provided that it has two or more carbon-carbon unsaturated double bonds per molecule and a melting point of not higher than 30° C., and is compatible with component (A).

The compound of component (C), having two or more carbon-carbon unsaturated double bonds per molecule and being compatible with component (A), acts as a crosslinking curing agent for the resin composition. For this reason, the resin composition according to the embodiment is considered to exhibit high reactivity.

If the melting point of the compound of component (C) exceeds 30° C., the viscosity of the varnish of the resin composition increases, which results in degraded impregnation properties of the varnish into the substrate when the prepreg is manufactured, and increased melt viscosity of the resin composition in heat molding. This may cause difficulty in molding of the prepreg.

Note that terms “component (C) compatible with component (A)” as referred herein means that component (C) and component (A) do not cause phase separation. Whether these components are compatible or incompatible with each other can be determined by the following procedure, for example. A film is prepared, by solvent casting, from a solution in which two resin components are dissolved. Then the resulting film is visibly observed to determine whether the film is transparent or opaque. When it is observed to be transparent, the two resin components are compatible with each other, while, when opaque, the two are incompatible.

A specific preferable example of the compound of component (C) is one expressed by the following Formula (8), for example.

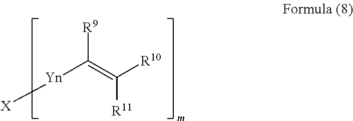

In Formula (8), “X” is any one of an arylene group, dicyclopentadienyl group, and isocyanurate group. “m” is an integer in a range from 1 to 3, inclusive, and depends on “X.” Each of R⁹ to R¹¹ is independently a hydrogen atom or an alkyl group. “Y” is one expressed by the following Formula (9) or (10).

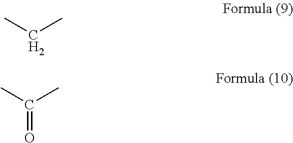

More specifically, examples of component (C) include: a trialkenyl isocyanurate compound such as triallyl isocyanurate (TAIC); a polyfunctional methacrylate compound having two or more methacrylic groups in its molecule; a polyfunctional acrylate compound having two or more acrylic groups in its molecule; and a vinylbenzyl compound such as styrene and divinylbenzene which have a vinylbenzyl group in its molecule. Among them, the compound having two or more carbon-carbon unsaturated double bonds in its molecule is preferably used. Superficially, preferable examples of the compound include a trialkenyl isocyanurate compound, a polyfunctional acrylate compound, a polyfunctional methacrylate compound, and a divinylbenzene compound. Use of one of these compounds is considered to enhance favorable crosslinking attributed to the curing reaction with component (A), resulting in increased heat resistance of the cured product of the resin composition according to the embodiment.

As component (C), the exemplified compound may be used solely or, alternatively, a combination of two or more compounds exemplified above may be used. Furthermore, a combination of the compound having two or more carbon-carbon unsaturated double bonds in its molecule and a compound having one carbon-carbon unsaturated double bond in its molecule may be employed. Specifically, examples of a compound having one carbon-carbon unsaturated double bond in its molecule include a compound (monovinyl compound) which has one vinyl group in its molecule.

Note that, with respect to 100 parts by mass of a sum of components (A) and (C), the content of component (A) is preferably not smaller than 65 parts by mass and not larger than 99 parts by mass, and more preferably not smaller than 75 parts by mass and not larger than 95 parts by mass. Moreover, with respect to 100 parts by mass of the sum of components (A) and (C), the content of component (C) is preferably not smaller than 1 part by mass and not larger than 35 parts by mass, and more preferably not smaller than 5 parts by mass and not larger than 25 parts by mass. When the contents of components (A) and (C) satisfy the ratio described above respectively, the cured product of the resin composition exhibits increased heat resistance and adhesion. This is considered to be because the curing reaction of components (A) and (C) favorably proceeds. Moreover, with respect to 100 parts by mass of the sum of components (A) and (C), the content of component (B) is preferably not smaller than 5 part by mass and not larger than 40 parts by mass, and more preferably not smaller than 10 parts by mass and not larger than 30 parts by mass. The content of component (B) in the range described above allows increased accuracy in thickness of the metal-clad laminate or the like manufactured using the compound, without a decrease in heat resistance of the cured product.

Note that the terms “content ratio” as referred herein means neither the compounding ratio of ingredients when the resin composition is prepared nor the component ratio of the resin composition in a varnish state, but means the component ratio of the resin composition in a so-called “B-stage state” in which the resin composition is semi-cured. The component ratio of each of the components of the resin composition in the B-stage state can be measured by means of a combination of NMR (nuclear magnetic resonance analysis), GC-MS (gas chromatography mass spectroscopy analysis), DI-MS (desorption ionization mass spectroscopy analysis), and the like.

The poly(phenylene ether) resin composition according to the embodiment may consist of these essential components, that is, components (A), (B), and (C). The poly(phenylene ether) resin composition may also further include other components together with these essential components. Such other components include an inorganic filler, a flame retardant, an additive agent, and a reaction initiator, for example. In particular, the resin composition according to the embodiment preferably further includes an inorganic filler as component (D).

The inorganic filler as component (D) is not limited to a specific one. Examples of the inorganic filler include: spherical silica, barium sulfate, silicon oxide powder, crushed silica, fired talc, barium titanate, titanium dioxide, clay, alumina, mica, boehmite, zinc borate, zinc stannate, and other metal oxides and metal hydrates. The inorganic filler contained in the resin composition can reduce thermal expansion of the metal-clad laminate or the like, resulting in increased dimensional stability of the metal-clad laminate or the like.

Moreover, silica is preferably used because it also allows increased heat resistance and dielectric loss tangent (Df) of the metal-clad laminate and the like.

In cases where the resin composition contains the inorganic filler of component (D), component (D) is preferably contained in a range from 40 parts by mass to 250 parts by mass, inclusive, with respect to 100 parts by mass of the sum of components (A), (B), and (C). When the content ratio of the inorganic filler falls within this range, it reliably allows increased accuracy in thickness of the metal-clad laminate and the printed-wiring board which both are manufactured using the resin composition. If the content ratio of the inorganic filler exceeds 250 parts by mass, it may cause a decrease in impregnation properties of the varnish into the substrate when the prepreg is manufactured, and a decrease in adhesion of the copper foil of the metal-clad laminate.

Moreover, the poly(phenylene ether) resin composition according to the embodiment preferably further includes a phosphorus-based flame retardant as component (E).

Containing component (E) allows a further enhanced flame retardance of the cured product of the poly(phenylene ether) resin composition. The phosphorus-based flame retardant is not limited to a specific one. Specifically, examples of the phosphorus-based flame retardant include a condensed phosphoric ester, a phosphoric ester compound such as cyclic phosphoric ester, a phosphazene compound such as a cyclic phosphazene compound, a phosphinate such as aluminum dialkylphosphinate, and a melamine-based flame retardant such as melamine phosphate and melamine polyphosphate.

Among them, the phosphorus-based flame retardant is more preferably at least one selected from the phosphinate compound, the phosphoric ester compound, and the phosphazene compound. As the flame retardant, the retardant exemplified above may be solely used or, alternatively, two or more different retardants exemplified above may be combined and used.

In cases where the poly(phenylene ether) resin composition according to the embodiment includes the phosphorus-based flame retardant, the phosphorus-based flame retardant is preferably contained such that the content of phosphorus atoms of the retardant is in a range from 1.5 parts by mass to 5.2 parts by mass, inclusive, with respect to 100 parts by mass of the sum of components (A), (B), and (C). That is, the content of the phosphorus-based flame retardant is preferably within a range with which the content of phosphorus atoms of the resin composition falls within the range described above. This content range of the phosphorus-based flame retardant allows a further enhanced flame retardance of the cured product without affecting the accuracy in thickness of the metal-clad laminate and the like, with the excellent dielectric characteristics inherent in the poly(phenylene ether) copolymer being preserved.

Moreover, as described above, the poly(phenylene ether) resin composition according to the embodiment may include other additive agents. Examples of the additive agents include: an antifoam agent such as a silicone-based antifoam agent and an acrylic ester-based antifoam agent, a thermal stabilizer, an antistatic agent, an ultraviolet absorbing agent, a dye and pigment, a lubricant, and a dispersing agent such as a wetting-dispersing agent.

Moreover, the poly(phenylene ether) resin composition according to the embodiment may include a reaction initiator, as described above. The poly(phenylene ether) resin composition itself is capable of developing a curing reaction at a high temperature because it contains component (A) of the modified poly(phenylene ether) copolymer and component (C) of the crosslinking curing agent. However, depending on process conditions, it is sometimes difficult to rise temperature enough to progress the curing. In this case, a reaction initiator may be added. The reaction initiator is not limited to a specific one as long as it can accelerate the curing reaction of component (A) and component (C). Specifically, the reaction initiator may be an oxidizer including: α, α′-bis(t-butylperoxy-m-isopropyl)benzene, 2,5-dimethyl-2,5-di(t-butylperoxy)-3-hexyne, benzoylperoxide, 3,3′,5,5′-tetramethyl-1,4-diphenoxyquinone, chloranil, 2,4,6-tri-t-butylphenoxyl, t-butylperoxyisopropyl monocarbonate, and azobisisobutylonitrile, for example. A metal salt of carboxylic acid and the like may be used together with the reaction initiator, as needed, thereby further accelerating the curing reaction. Among them, α, α′-bis(t-butylperoxy-m-isopropyl)benzene is preferably used. The reaction initiation temperature allowed by using a, a′-bis(t-butylperoxy-m-isopropyl)benzene is relatively high, which can retard unnecessary acceleration of the curing reaction while the curing is not needed during drying the prepreg, for example. This also allows prevention of a decrease in shelf life quality (storage stability) of the poly(phenylene ether) resin composition. In addition, as α, α′-bis(t-butylperoxy-m-isopropyl)benzene is less volatile, it does not volatilize during drying and storing of the prepreg, resulting in excellent stability. Furthermore, the reaction initiator may be solely used or, alternatively, two or more different reaction initiators may be combined and used.

In cases where the prepreg is manufactured, the poly(phenylene ether) resin composition according to the embodiment is often prepared in a varnish state, so that a substrate (fibrous substrate) is impregnated with the poly(phenylene ether) resin composition to form the prepreg. That is, such a poly(phenylene ether) resin composition is usually available in a prepared varnish state (resin varnish). The resin varnish is prepared in the following manner, for example.

First, organic-solvent-soluble components including components (A), (B), and (C) and compatible flame retardants are charged and dissolved in an organic solvent. If necessary, the organic-solvent solution may be heated. After that, other components such as inorganic filler and an incompatible flame retardant, for example, which are used on an as needed basis and insoluble in organic solvents, are added to the organic-solvent solution. The resulting slurry is then dispersed to be in a predetermined dispersion state with a ball mill, a bead mill, a planetary mixer, a roll mill, or the like. In this way, the varnish-state resin composition is prepared. The organic solvent used here is not limited to a specific one as long as it can dissolve components (A), (B), and (C), the compatible flame retardants, etc. and does not hinder the curing reaction. Specifically, examples of the organic solvent include toluene and the like.

Note that, during processes of the varnish into a semi-cured product (prepreg) in a B-stage state via a drying by heating process to be described later, component (C) sometimes volatilizes which is contained in the poly(phenylene ether) resin composition according to the embodiment. For this reason, the compounding ratio of each component of the varnish is different from the component ratio of corresponding component of the resulting prepreg. Accordingly, compounding ratio of each component of the varnish needs to be adjusted such that the component ratio of each component of the resulting semi-cured product (prepreg) in B-stage will be in the range described above. Such adjustment may be carried out as follows: For example, the amount of component (C) is estimated in advance which would volatilize during the drying by heating process for making the B-stage resin composition. Then, the compounding amount of each component of the resin composition in the varnish preparation step is determined by back calculation from the thus-estimated amount of volatilizing component (C) such that the content ratio of each component of the resulting B-stage resin composition will be a predetermined value.

Specifically, in the case of the commonly-adopted process (drying by heating process) of fabricating the prepreg using the resin varnish, when divinylbenzene is used as component (C), a substrate with a thickness of 0.1 mm is impregnated with the resin varnish, followed by drying by heating at 130° C. for approximately 3 minutes. During this process, about 80% of the divinylbenzene volatilizes. Accordingly, in the case where a drying by heating process is applied, the amount of divinylbenzene is preferably adjusted in the step of preparing the varnish such that the compounding ratio of divinylbenzene will be approximately 5 times larger than the content ratio of divinylbenzene of the B-stage varnish.

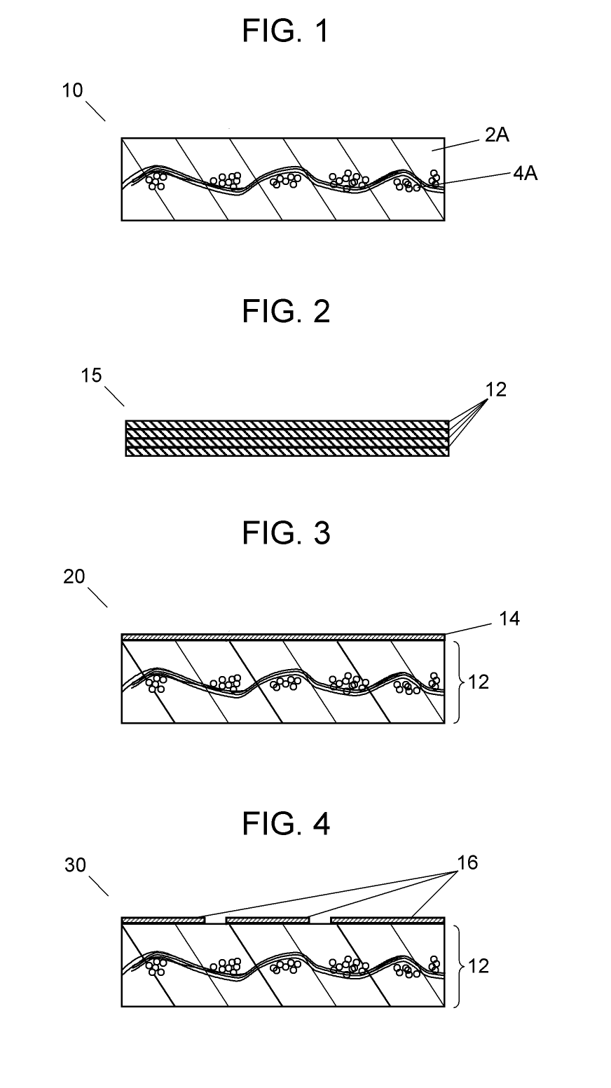

Next, a description will be made regarding the prepreg using the resin composition according to the embodiment, with reference to FIG. 1. FIG. 1 is a cross-sectional view of the prepreg according to the embodiment. Prepreg 10 is fabricated by impregnating substrate 4A with resin composition 2A. Specifically, prepreg 10 is manufactured by using resin composition 2A in a liquid or varnish state. For example, the manufacturing method includes impregnating substrate 4A with either liquid-state resin composition 2A or varnish-state resin composition 2A, and drying it. Moreover, prepreg 10 may be in a state where resin composition 2A with which substrate 4A is impregnated becomes in a semi-cured state by heating substrate 4A impregnated with resin composition 2A. That is, prepreg 10 in the semi-cured state (B-stage) is fabricated by heating substrate 4A after being impregnated with resin composition 2A, under desired heating conditions, e.g. heating at a temperature of 80° C. to 170° C. for 1 to 10 minutes.

Substrate 4A is not limited to a specific one as long as it is a fibrous substrate which can be used for manufacturing printed-wiring boards. Specifically, examples of the fibrous substrate include glass cloth, aramid cloth, polyester cloth, glass nonwoven fabric, aramid nonwoven fabric, polyester nonwoven fabric, pulp paper, and linter paper. Note that use of the glass cloth allows the fabrication of a metal-clad laminate and a printed-wiring boards which both feature high mechanical strength. In particular, a flattening-pressed glass cloth is preferably used. Specifically, such a flattening-pressed glass cloth can be formed by a flattening process in which a sheet of glass cloth is continuously pressurized at an appropriate pressure with press rolls such that yarn of the glass cloth can be compressed to form a flat shape, for example. Incidentally, the thickness of substrate 4A is commonly from 0.04 mm to 0.3 mm, for example.

Resin composition 2A is used for impregnating substrate 4A by clipping, applying, or the like. The impregnation can be repeated a plurality of times, if necessary. At that time, the impregnation can be repeated by using a plurality of the resin compositions with different compositions (contents) and/or concentrations from one another. This allows adjustment of the composition and the amount of the resin, which finally achieves the targeted ones.

As described above, prepreg 10 for fabricating a printed-wiring board includes substrate 4A and resin composition 2A with which substrate 4A is impregnated. Such prepreg 10 is so excellent in circuit filling properties that even complicated circuits can be easily formed without voids when the printed-wiring board is fabricated. Moreover, the thus-fabricated metal-clad laminate and the printed-wiring board exhibit excellent accuracy in thickness, even in the package applications where a semiconductor chip is joined and mounted in the package. For this reason, such a package can feature ease of mounting the chip therein and advantages of small quality variations in signal speed, impedance, and the like.

Next, descriptions will be made regarding laminate 15, metal-clad laminate 20, and printed-wiring board 30 which use prepreg 10, with reference to FIGS. 2 to 4.

Laminate 15 as shown in FIG. 2 is fabricated by laminating a plurality of sheets of prepreg 10, followed by molding and curing. Specifically, the plurality of sheets of prepreg 10 is laminated on one another. The thus-laminated body is subjected to a heating and pressurizing process to form a one-piece laminate, thereby completing laminate 15. The pressurizing conditions are appropriately set in accordance with the thickness of laminate 15 to be manufactured, the kind of resin composition 2A contained in prepreg 10, and the like. For example, the temperature can be from 170° C. to 220° C., the pressure can be from 1.5 to 5.0 MPa, and the time period can be from 60 to 150 minutes. Note that, only one sheet of prepreg 10 may be formed and cured to fabricate an insulating substrate. That is, laminate 15 is a kind of insulating substrates.

As described above, laminate 15 includes the plurality of insulating layers 12 laminated on one another. Each of the insulating layers 12 is the cured product of prepreg 10 shown in FIG. 1. As laminate 15 contains, as a resin component, the cured material of resin composition 2A, laminate 15 has good heat dissipation and high product stability such as moisture resistance.

Moreover, as shown in FIG. 3, metal-clad laminate 20 is fabricated by overlapping or laying metal foil 14 such as copper foil on one side of prepreg 10, and heating and pressurizing them to form a one-piece laminate, for example. That is, metal-clad laminate 20 includes insulating layer 12 which is the cured product of prepreg 10 shown in FIG. 1, and metal foil 14 laminated on insulating layer 12. Alternatively, two sheets of metal foil 14 may be laminated on the both sides of prepreg 10, respectively. Moreover, for the metal-clad laminate, a plurality of sheets of prepreg 10 may be laminated and used or, alternatively, laminate 15 instead of prepreg 10 may be used.

Furthermore, one or more sheets of prepreg 10 and metal foil 14 may be laminated, and then heated and pressurized to form a one-piece laminate, i.e. metal-clad laminate 20, then, metal foil 14 may be removed from thus-formed metal-clad laminate 20 to fabricate an insulating substrate or laminate 15.

The heating-pressurizing conditions may be comparable with those for fabricating laminate 15. Metal-clad laminate 20, being containing the cured material of resin composition 2A, exhibits good heat dissipation and high product stability such as moisture resistance.

Moreover, as shown in FIG. 4, printed-wiring board 30 using prepreg 10 can be fabricated from metal-clad laminate 20. That is, printed-wiring board 30 is fabricated by making metal foil 14 on metal-clad laminate 20 into a circuit. Specifically, metal foil 14 can be etched to form the circuit to fabricate printed-wiring board 30 having a surface on which conductive pattern 16 is disposed as the circuit.

That is, printed-wiring board 30 includes insulating layer 12 which is the cured product of prepreg 10 shown in FIG. 1, and conductive pattern 16 formed on insulating layer 12. Printed-wiring board 30 is excellent in dielectric characteristics and accuracy in thickness. Use of printed-wiring board 30 even in package applications, where a semiconductor chip is joined and mounted, allows the feature of ease of mounting the chip and advantages of small variations in quality in terms of signal transmission speed, impedance, and the like.

Hereinafter, the embodiment will be described more specifically by using Examples; however, the scope of the present disclosure is not limited to these Examples.

### Examples

First, some kinds of modified poly(phenylene ether) are synthesized. Note that the number of terminal hydroxyl groups is defined to be the average number of phenolic hydroxyl groups in molecule terminals per molecule of a poly(phenylene ether).

### Synthesis of Modified Poly(Phenylene Ether) 1 (Modified PPE 1)

Modified poly(phenylene ether) 1 (Modified PPE 1) is prepared by reaction of the poly(phenylene ether) with chloromethylstyrene. Specifically, first, a 1-liter three-necked flask equipped with a temperature controller, a stirrer, a cooling apparatus, and a dropping funnel is prepared. The flask is charged with 200 g of the poly(phenylene ether), 30 g of a mixture (50:50 mass ratio) of p-chloromethylstyrene and m-chloromethylstyrene, 1.227 g of tetra-n-butylammonium bromide, and 400 g of toluene. Then, these mixed materials are stirred until the toluene dissolves the poly(phenylene ether), chloromethylstyrene, and tetra-n-butylammonium bromide. During stirring, these materials are gradually heated until the temperature of the liquid finally reaches 75° C.

Note that the poly(phenylene ether) used here is SA90 with the structure expressed by Formula (5), manufactured by SABIC Innovative Plastics. The SA90 has an intrinsic viscosity (IV) of 0.083 dl/g, the number of terminal hydroxyl groups of 1.9, and a Mw of 1700. Moreover, the mixture of p-chloromethylstyrene and m-chloromethylstyrene is chloromethylstyrene (CMS) manufactured by Tokyo Chemical Industry Co., Ltd. The tetra-n-butylammonium bromide acts as a phase-transfer catalyst.

After that, an aqueous solution of sodium hydroxide (20 g of sodium hydroxide/20 g of water), i.e. an alkali metal hydroxide, is added by dropping to the solution for 20 minutes. Then, the solution is further stirred at 75° C. for 4 hours.

Next, after the content of the flask is neutralized by hydrochloric acid (10 mass %), a large amount of methanol is poured into the flask, thereby forming a precipitate in the liquid in the flask. That is, the product contained in the reaction liquid in the flask is re-precipitated. After that, the precipitate is taken out by filtering and then washed three times with a mixed solution of methanol and water in a mass ratio of 80:20, followed by drying at 80° C. in a reduced pressure for 3 hours.

The resulting solid is analyzed by ¹H-NMR (400 MHz, CDCl3, TMS). The analysis shows an ethenybenzyl-derived peak at 5 to 7 ppm. Accordingly, the resulting solid is confirmed to be the modified poly(phenylene ether) which has a group expressed by Formula (1) in its molecule terminal. That is, modified PPE 1 is the poly(phenylene ether) having undergone ethenylbenzylation.

In addition, modified PPE 1 is measured by GPC to obtain its molecular weight distribution. By calculation using the resulting molecular weight distribution, it is confirmed that the Mw of modified PPE 1 is 1,900.

Moreover, the number of terminal function groups of modified PPE 1 is measured in the following manner. First, an amount of modified PPE 1 is correctly weighed. The measured weight is designated by X (mg). Then, weighed modified PPE 1 is dissolved in 25 ml of methylene chloride. This solution is added with 100 μl of an ethanol solution of 10 mass % tetraethylammonium hydroxide (TEAH). In the ethanol solution, the volume ratio of TEAH to ethanol is 15:85. After that, absorbance (Abs) at 318 nm of the solution is measured by a UV spectrophotometer (UV-1600 manufactured by SHIMADZU CORPORATION). From the measurement result, the number of the terminal hydroxyl groups of the modified poly(phenylene ether) is calculated by using the following equation.

The amount of residual OH (μmol/g)=[(25×Abs)/(∈×OPL×X)]×10⁶

In the equation, “∈” is the absorbance coefficient of 47001/mol·cm; OPL is the cell optical path length of 1 cm.

The thus-calculated amount of the residual OH (the number of the terminal hydroxyl groups) of modified PPE 1 is approximately zero. From this result, it is confirmed that almost all of the hydroxyl groups of poly(phenylene ether) prior to modification are modified. In this case, the decrease in the number of the terminal hydroxyl groups from the poly(phenylene ether) prior to modification corresponds to the number of the terminal hydroxyl groups of the poly(phenylene ether) prior to the modification. Then it can be seen that the number of the terminal hydroxyl groups of the poly(phenylene ether) prior to the modification is equal to the number of the terminal function groups of modified PPE 1. Accordingly, the number of the terminal function groups is 1.8.

### Synthesis of Modified Poly(Phenylene Ether) 2 (Modified PPE 2)

Modified PPE 2 is synthesized in the same method as that for synthesizing modified PPE 1 except for use of different poly(phenylene ether) to be described later and the following conditions.

The poly(phenylene ether) used here is SA120 manufactured by SABIC Innovative Plastics which has an intrinsic viscosity (IV) of 0.125 dl/g, the number of terminal hydroxyl groups of 1 (one), and Mw of 2400.

Next, the poly(phenylene ether) is processed to react with chloromethylstyrene in the following conditions. For the reaction, used are 200 g of the poly(phenylene ether) (SA120), 15 g of CMS, 0.92 g of tetra-n-butylammonium bromide, and an aqueous solution of sodium hydroxide (10 g of sodium hydroxide/10 g of water) instead of the aqueous solution of sodium hydroxide (20 g of sodium hydroxide/20 g of water). Except for this, the conditions are the same as those for synthesizing modified PPE 1.

Then, the resulting solid is analyzed in the same manner as that for modified PPE 1. An ethenybenzyl-derived peak is observed at 5 to 7 ppm.

From this result, it is confirmed that the resulting solid is the modified poly(phenylene ether) which has a vinylbenzyl group, i.e. a substitute group, in its molecule. That is, modified PPE 2 is the poly(phenylene ether) having undergone ethenylbenzylation.

Moreover, the number of terminal function groups of modified PPE 2 is measured in the same manner as that described above. The measurement confirms that the number of the terminal function groups is 1 (one).

Moreover, the IV of modified PPE 2 is measured in the same manner as that described above. The measurement confirms that the IV is 0.125 dl/g.

Moreover, the Mw of modified PPE 2 is measured in the same manner as that described above. The measurement confirms that the Mw is 2,800.

Hereinafter, the components used in preparing the poly(phenylene ether) resin composition will be described.

[Component (A): Poly(Phenylene Ether)]
Modified PPE 1: modified poly(phenylene ether) 1 obtained by the synthesis method described above is used.
Modified PPE 2: modified poly(phenylene ether) 2 obtained by the synthesis method described above is used.
Modified PPE 3: SA9000 manufactured by SABIC Innovative Plastics is used which is the modified poly(phenylene ether) in which the terminal hydroxyl groups of the poly(phenylene ether) expressed by Formula (7) are modified with methacrylic groups. It has Mw of 1700, and 2 terminal functional groups.
Unmodified PPE 1: SA120 manufactured by SABIC Innovative Plastics is used which is the poly(phenylene ether) that has a hydroxyl group in its terminal. It has IV of 0.125 dl/g, Mw of 2600, and one terminal hydroxyl group.

[Component (B): Polymer Substance]
As polymer substance with a polystyrene framework, GPPS 680 as polystyrene manufactured by PS Japan Corporation is used. It has Mw of 190,000, and a softening temperature of 98° C.
As polymer substance with a polystyrene framework and a polybutadiene framework, Ricon 184 as a butadiene-styrene copolymer manufactured by Cray Valley is used. It has Mw of 11,000, and a softening temperature of not higher than 10° C. That is, Ricon 184 is a liquid at room temperature.
As polymer substance with a methacrylate framework, Teisan Resin SG-P3 as an acryl resin manufactured by Nagase ChemteX Corporation is used. It has Mw of 850000, and a softening temperature of −10° C.
As another polymer substance with a polystyrene framework, FTR8100 as styrene-based copolymer manufactured by Mitsui Chemicals, Inc. is used. It has Mw of 1,240, and a softening temperature of 100° C.
As further another polymer substance with a polystyrene framework, HIMER ST-120 as polystyrene manufactured by Sanyo Chemical Industries, Ltd. is used. It has Mw of 10,000, and a softening temperature of 120° C.

Note that the softening temperatures of the polymer substances are measured in accordance with test-method B50 (test load of 50N, temperature rising rate of 50° C./h) described in Japanese Industrial Standard JIS K7206 (corresponding to ISO 306 1994). The Mw values of GPPS 680, Teisan Resin SG-P3, FTR8100, and HIMER ST-120 can be obtained by referring to data listed in respective manufacture's product catalogs.

Moreover, the Mw of Ricon 184 is measured by GPC. Specifically, the measurement is carried out using; a HLC-8120GPC, a GCP apparatus, manufactured by Tosoh Corporation; two columns of Super HM-H manufactured by Tosoh Corporation; and monodisperse polystyrene as a standard reference material manufactured by Tosoh Corporation.

[Component (C): Compound (Crosslinking Curing Agent)]
triallyl isocyanurate (TAIC) manufactured by Nippon Kasei Chemical Co., Ltd.
tricyclodecane dimethanol dimethacrylate, DCP manufactured by Shin Nakamura Chemical Co., Ltd.
divinylbenzene; DVB810 manufactured by NIPPON STEEL & SUMIKIN CHEMICAL Co., Ltd.

[Component (D): Inorganic Filler]
Spherical silica of which surface is treated with vinylsilane: SC2300-SVJ manufactured by Admatechs Co., Ltd.

[Component (E): Flame Retardant]
Phosphinate compound: OP-935 (phosphorus concentration of 23%) manufactured by Clariant (Japan) K.K.
Phosphoric ester compound: PX-200 (phosphorus concentration of 8%) manufactured by DAIHACHI CHEMICAL INDUSTRY Co., Ltd.
Phosphazene compound: SPB100 (phosphorus concentration of 13%) manufactured by Otsuka Chemical Co., Ltd.

[Reaction Initiator]

1, 3-bis(butyl peroxyisopropyl)benzene: PERBUTYL P manufactured by NOF Corporation.

Method of Preparation

[Resin Varnish]

First, the modified poly(phenylene ether) as component (A) and toluene are mixed. The mixture is heated to 80° C. to dissolve component (A) in the toluene. Thus, the toluene solution of 50 mass % component (A) is prepared. After that, the toluene solution is added with a polymer substance as component (B) and a crosslinking curing agent as component (C) in the proportions described in Tables 1 to 4, and then stirred for 30 minutes to completely dissolve components (B) and (C). Then, the solution is further added with a reaction initiator to form a mixture. This mixture is homogenized with a bead mill to prepare the resin composition in a varnish state (resin varnish). Note that, in cases of the preparations of some other samples, the mixture is further added with an inorganic filler as component (D) and a flame retardant as component (E), at the same time of adding the reaction initiator.

[Prepreg]

Prepreg is fabricated using the resin varnish described above. The prepreg is subjected to evaluation to be described.

For the prepreg, used is a substrate which is Type #2116 WEA116E glass cloth manufactured by NITTO BOSEKI Co., Ltd. Then, the substrate is impregnated with the resin varnish described above such that the thickness of the post-curing substrate becomes 125 μm. After that, the resin varnish-impregnated substrate is dried by heating at 130° C. for 3 minutes until the resin varnish becomes in a semi-cured state, thereby preparing the prepreg.

[Metal-Clad Laminate]

A Laminate is formed as follows. Six sheets of the prepreg described above are laminated on one another, and then two sheets of copper foil with a thickness of 35 μM are disposed on the both sides of the laminate body, respectively, to form the laminate. The copper foil is GT-MP manufactured by Furukawa Electric Co., Ltd. Then, the resulting laminate is heated while pressurized in vacuum, at 200° C., under a pressure of 40 kgf/cm², for 120 minutes. In this way, copper-clad laminate 1 with a thickness of 0.75 mm is fabricated, with the copper foil being bonded on the both sides of the sheet.

Moreover, copper-clad laminate 2 with a thickness of 0.125 mm is fabricated, using 1 (one) sheet of the prepreg described above, in the same manner as described above.

The thus-fabricated prepreg and laminates for evaluation are subjected to the evaluation in the following method.

[Accuracy in Thickness (Variations in Thickness)]

A laminate is fabricated by removing the copper foil by etching from copper-clad laminate 1 with a rectangular shape of 340 mm×510 mm. The laminate is cut diagonally. The thickness of the laminate is measured at positions 5 mm inside the cutting plane, with a micrometer (MDC-25SX manufactured by Mitsutoyo Corporation). At this time, the thicknesses at 29 positions of the diagonally-cut laminate are measured in the following manner: A center portion of the sheet is first measured, and then 14 portions are measured at positions in each of left and right lines, parallel to the cutting line, extending from the center portion, with the positions being separated from one another at regular intervals of 20 mm, i.e. total 29 positions are measured. The evaluation of the laminate is carried out in the following manner: The laminate which shows a smaller difference (i.e. smaller variations) between the maximum and minimum thicknesses among the 29 measurements is evaluated to be the laminate with higher accuracy in thickness. The tables show the differences, as thickness variations, between the maximum and minimum thicknesses among the thicknesses of the 29 portions. Note that, the center portion of the laminate can be visually observed. The both ends of the glass cloth are positioned at the both ends of the laminate; therefore, the center of the glass cloth corresponds to the center portion of the laminate.

[Circuit Filling Properties]

Pattern A (Coarse Pattern)

A lattice pattern circuit is formed in the copper foil disposed on each of the both sides of copper-clad laminate 1 such that a residue rate of copper is 50%. Then, each side of copper-clad laminate 1 with the thus-formed circuits is laminated with a sheet of the prepreg, followed by heating and pressurizing under the same conditions as those with which copper-clad laminate 1 is fabricated. The thus-formed laminates (laminate bodies for evaluation) are evaluated in the following manner: The laminate is evaluated to be “good (GD)” when the prepreg-derived resin and the like sufficiently enter between the conductive patterns and yet when no void is formed therein. That is, when no void is observed between the conductive patterns, the laminate is evaluated to be “GD.” In contrast, the laminate is evaluated to be “no good (NG)” when the prepreg-derived resin insufficiently enters between the conductive patterns and the formation of a void therein is observed. Such a void can be visually observed.

Pattern B (Fine Pattern)

Lattice pattern circuits are formed in the copper foil disposed on each of the both sides of copper-clad laminate 1. Such lattice pattern circuits have different patterns from one another such that different residue rates of copper are 20%, 40%, 50%, 60%, and 80%. Then, each side of copper-clad laminate 1 with the thus-formed circuits is laminated with a sheet of the prepreg, followed by heating and pressurizing under the same conditions as those with which copper-clad laminate 1 is fabricated. The thus-formed laminates (laminate bodies for evaluation) are evaluated in the following manner: The laminate is evaluated to be “good (GD)” when the prepreg-derived resin and the like sufficiently enter between the conductive patterns of all of the circuits with the different copper residue rates and yet when no void is formed in all of the circuits. That is, when no void is observed between the conductive patterns in all of the circuits, the laminate is evaluated to be “GD.” When a void is observed in some of the circuits, the laminate is evaluated to be “OK.” When a void is observed in all of the circuits, the laminate is evaluated to be “NG.”

[Dielectric Characteristics (Specific permittivity and Dielectric Loss Tangent)]

The laminates for evaluation are measured in terms of specific permittivity and dielectric loss tangent at 10 GHz by the cavity-resonator perturbation method. The laminates for the evaluation are ones prepared by removing the copper foil from copper-clad laminate 1. Specifically, the specific permittivity and dielectric loss tangent of the laminates are measured at 10 GHz with a network analyzer (N5230A manufactured by Agilent Technologies Japan, Ltd.).

[CTE (Coefficient of Thermal Expansion)]

Specimens for CTE measurement are prepared by removing the copper foil from copper-clad laminates 2 described above. These specimens are measured in such a manner that coefficients of thermal expansion in a planar direction of the cured resin products are measured at temperatures lower than their glass transition temperatures by the TMA (Thermo-Mechanical Analysis) method in accordance with Japanese Industrial Standard JIS C 6481 (corresponding to IEC 60249-1 1982). The measurement is carried out with a TMA apparatus (TMA6000 manufactured by SII Nano Technology Inc.).

[Adhesion Strength of Copper Foil]

Peel strength of the copper foil from the insulating layers of copper-clad laminate 1 is measured in accordance with Japanese Industrial Standard JIS C 6481. Specifically, a pattern with a rectangular shape of 10 mm width and 100 mm length is formed by etching the copper foil. The pattern is peeled off at a peeling speed of 50 mm/min with a pulling-test machine to measure the peel strength of the pattern. The thus-measured peel strength is determined as the copper adhesion strength.

[Heat Resistance]

Heat resistance of the metal-clad laminate is evaluated in accordance with Japanese Industrial Standard JIS C 6481. Specifically, test pieces, each 50 mm×50 mm in size, are cut from copper-clad laminate 1. These test pieces are divided into three groups and left, for 1 hour, in constant temperature chambers at different setting temperatures of 270° C., 280° C., and 290° C., respectively. After that, these test pieces are taken out from the chambers and subjected to the evaluation. The evaluation is carried out in the following manner: When no blister in the test piece treated at 290° C. is visually observed, the test piece is evaluated to be “EX;” when no blister in the piece treated at 280° C. is observed, evaluated to be “GD;” when no blister in the piece treated at 270° C. is observed, evaluated to be “OK;” when a blister in the piece at 270° C. is observed, evaluated to be “NG.”

The results from these evaluations described above are shown in Tables 1 to 4.

TABLE 1

| | | | S.T./ | | | | | | | |
|---|---|---|---|---|---|---|---|---|---|---|
| | | | M.P. | | | | | | | |
| Content | | Mw | (° C.) | E1 | E2 | E3 | E4 | E5 | E6 | E7 |
| A | Modified PPE 1 | 1900 | — | 90 | | | 90 | 90 | 90 | 90 |
| | Modified PPE 2 | 2800 | — | | 90 | | | | | |
| | Modified PPE 3 | 1700 | — | | | 90 | | | | |
| | Unmodified PPE | 2600 | — | | | | | | | |
| B | GPPS 680 | 1.9 × 10⁵ | 98 | 10 | 10 | 10 | 10 | 10 | | |
| | Ricon 184 | 1.1 × 10⁴ | <10 | | | | | | 10 | |
| | SG-P3 | 8.5 × 10⁵ | −10 | | | | | | | 10 |
| | FTR 8100 | 1240 | 100 | | | | | | | |
| | ST 120 | 1.0 × 10⁴ | 120 | | | | | | | |
| C | DCP | — | <25 | 10 | 10 | 10 | | | 10 | 10 |
| | DVB 810 | — | −30 | | | | 10 | | | |
| | TAIC | — | 23-27 | | | | | 10 | | |
| D | SC2300-SVJ | — | — | 110 | 110 | 110 | 110 | 110 | 110 | 110 |
| E | OP-935 | — | — | | | | | | | |
| | PX-200 | — | — | | | | | | | |
| | SPB 100 | — | — | | | | | | | |

| | | | | | | | | | |
|---|---|---|---|---|---|---|---|---|---|
| Reaction Initiator | — | — | 2 | 2 | 2 | 2 | 2 | 2 | 2 |

| (Sum) | | 222 | 222 | 222 | 222 | 222 | 222 | 222 |
|---|---|---|---|---|---|---|---|---|
| P-atom Content (%) | | 0 | 0 | 0 | 0 | 0 | 0 | 0 |
| Evaluation | Variations in Thickness (μm) | 15 | 15 | 15 | 15 | 15 | 17 | 12 |
| | Circuit Filling Properties Pattern A | GD | GD | GD | GD | GD | GD | GD |
| | Circuit Filling Properties Pattern B | GD | GD | GD | GD | GD | GD | GD |
| | Specific permittivity | 3.5 | 3.7 | 3.7 | 3.6 | 3.6 | 3.5 | 3.5 |
| | Dielectric Loss Tangent | 0.005 | 0.005 | 0.005 | 0.0045 | 0.005 | 0.005 | 0.006 |
| | CTE (K⁻¹) | 12 | 12 | 12 | 12 | 12 | 12 | 12 |
| | Copper Foil Adhesion Strength (kN/m) | 0.6 | 0.5 | 0.5 | 0.6 | 0.6 | 0.6 | 0.6 |
| | Heat Resistance | GD | GD | GD | GD | GD | GD | GD |

Mw: Weight-average molecular weight
S.T.: Softening temperature
M.P.: Melting point

TABLE 2

| | | | S.T./ | | | | | |
|---|---|---|---|---|---|---|---|---|
| | | | M.P. | | | | | |
| Content | | Mw | (° C.) | C1 | C2 | C3 | C4 | C5 |
| A | Modified PPE 1 | 1900 | — | 90 | 90 | 90 | 60 | |
| | Modified PPE 2 | 2800 | — | | | | | |
| | Modified PPE 3 | 1700 | — | | | | | |
| | Unmodified PPE | 2600 | — | | | | | 90 |
| B | GPPS 680 | 1.9 × 10⁵ | 98 | | | | 10 | 10 |
| | Ricon 184 | 1.1 × 10⁴ | <10 | | | | | |
| | SG-P3 | 8.5 × 10⁵ | −10 | | | | | |
| | FTR 8100 | 1240 | 100 | 10 | | | | |
| | ST 120 | 1.0 × 10⁴ | 120 | | 10 | | | |
| C | DCP | — | <25 | 10 | 10 | 10 | | 10 |
| | DVB 810 | — | −30 | | | | | |
| | TAIC | — | 23-27 | | | | | |
| D | SC2300-SVJ | — | — | 110 | 110 | 100 | 100 | 110 |
| E | OP-935 | — | — | | | | | |
| | PX-200 | — | — | | | | | |
| | SPB 100 | — | — | | | | | |

| | | | | | | | |
|---|---|---|---|---|---|---|---|
| Reaction Initiator | — | — | 2 | 2 | 2 | 2 | 2 |

| (Sum) | | 222 | 222 | 202 | 202 | 222 |
|---|---|---|---|---|---|---|
| P-atom Content (%) | | 0 | 0 | 0 | 0 | 0 |
| Evaluation | Variations in Thickness (μm) | 60 | 17 | 75 | 30 | 20 |
| | Circuit Filling Properties Pattern A | GD | NG | GD | GD | GD |
| | Circuit Filling Properties Pattern B | GD | NG | GD | GD | GD |
| | Specific permittivity | 3.5 | 3.5 | 3.5 | 3.8 | 4.1 |
| | Dielectric Loss Tangent | 0.005 | 0.005 | 0.005 | 0.009 | 0.01 |
| | CTE (K⁻¹) | 12 | 12 | 12 | 16 | 13 |
| | Copper Foil Adhesion Strength (kN/m) | 0.6 | 0.5 | 0.7 | 0.3 | 0.3 |
| | Heat Resistance | GD | GD | GD | NG | NG |

Mw: Weight-average molecular weight
S.T.: Softening temperature
M.P.: Melting point

TABLE 3

| | | | S.T./ | | | | | | | | |
|---|---|---|---|---|---|---|---|---|---|---|---|
| | | | M.P. | | | | | | | | |
| Content | | Mw | (° C.) | E8 | E9 | E10 | E11 | E12 | E13 | E14 | E15 |
| A | Modified PPE 1 | 1900 | — | 90 | 90 | 90 | 90 | 75 | 65 | 90 | 60 |
| | Modified PPE 2 | 2800 | — | | | | | | | | |
| | Modified PPE 3 | 1700 | — | | | | | | | | |
| | Unmodified PPE | 2600 | — | | | | | | | | |
| B | GPPS 680 | 1.9 × 10⁵ | 98 | 10 | 10 | 10 | 10 | 10 | 10 | 30 | 40 |
| | Ricon 184 | 1.1 × 10⁴ | <10 | | | | | | | | |
| | SG-P3 | 8.5 × 10⁵ | −10 | | | | | | | | |
| | FTR 8100 | 1240 | 100 | | | | | | | | |
| | ST 120 | 1.0 × 10⁴ | 120 | | | | | | | | |
| C | DCP | — | <25 | 10 | 10 | 10 | 10 | 25 | 35 | 10 | 10 |
| | DVB 810 | — | −30 | | | | | | | | |
| | TAIC | — | 23-27 | | | | | | | | |
| D | SC2300-SVJ | — | — | 0 | 44 | 275 | 330 | 110 | 110 | 130 | 110 |
| E | OP-935 | — | — | | | | | | | | |
| | PX-200 | — | — | | | | | | | | |
| | SPB 100 | — | — | | | | | | | | |

| | | | | | | | | | |
|---|---|---|---|---|---|---|---|---|---|
| Reaction Initiator | — | 2 | 2 | 2 | 2 | 2 | 2 | 2 | 2 |

| (Sum) | | 112 | 156 | 387 | 442 | 222 | 222 | 262 | 222 |
|---|---|---|---|---|---|---|---|---|---|
| P-atom Content (%) | | 0 | 0 | 0 | 0 | 0 | 0 | 0 | 0 |
| Evaluation | Variations in Thickness (μm) | 22 | 20 | 9 | 6 | 17 | 18 | 12 | 9 |
| | Circuit Filling Properties Pattern A | GD | GD | GD | GD | GD | GD | GD | GD |
| | Circuit Filling Properties Pattern B | GD | GD | OK | NG | GD | GD | GD | GD |
| | Specific permittivity | 3.3 | 3.4 | 3.8 | 3.9 | 3.6 | 3.7 | 3.4 | 3.3 |
| | Dielectric Loss Tangent | 0.006 | 0.006 | 0.004 | 0.004 | 0.0055 | 0.006 | 0.005 | 0.0045 |
| | CTE (K⁻¹) | 15 | 14 | 10 | 8 | 11 | 11 | 13 | 13 |
| | Copper Foil Adhesion Strength (kN/m) | 0.8 | 0.7 | 0.4 | 0.3 | 0.6 | 0.4 | 0.5 | 0.4 |
| | Heat Resistance | OK | GD | EX | EX | GD | OK | GD | OK |

Mw: Weight-average molecular weight
S.T.: Softening temperature
M.P.: Melting point

TABLE 4

| | | | S.T./ | | | |
|---|---|---|---|---|---|---|
| | | | M.P. | | | |
| Content | | Mw | (° C.) | E16 | E17 | E18 |
| A | Modified PPE 1 | 1900 | — | 90 | 90 | 90 |
| | Modified PPE 2 | 2800 | — | | | |
| | Modified PPE 3 | 1700 | — | | | |
| | Unmodified PPE | 2600 | — | | | |
| B | GPPS 680 | 1.9 × 10⁵ | 98 | 10 | 10 | 10 |
| | Ricon 184 | 1.1 × 10⁴ | <10 | | | |
| | SG-P3 | 8.5 × 10⁵ | −10 | | | |
| | FTR 8100 | 1240 | 100 | | | |
| | ST 120 | 1.0 × 10⁴ | 120 | | | |
| C | DCP | — | <25 | 10 | 10 | 10 |
| | DVB 810 | — | −30 | | | |
| | TAIC | — | 23-27 | | | |
| D | SC2300-SVJ | — | — | 110 | 110 | 100 |
| E | OP-935 | — | — | 15 | 10 | 10 |
| | PX-200 | — | — | | 5 | |
| | SPB 100 | — | — | | | 5 |

| | | | | |
|---|---|---|---|---|
| Reaction Initiator | — | 2 | 2 | 2 |

| (Sum) | | 237 | 237 | 237 |
|---|---|---|---|---|
| P-atom Content (%) | | 3 | 2.6 | 2.3 |
| Evaluation | Variations in Thickness (μm) | 12 | 17 | 17 |
| | Circuit Filling Properties Pattern A | GD | GD | GD |
| | Circuit Filling Properties Pattern B | GD | GD | GD |
| | Specific permittivity | 3.5 | 3.5 | 3.4 |
| | Dielectric Loss Tangent | 0.006 | 0.005 | 0.0045 |
| | CTE (K⁻¹) | 11 | 14 | 14 |
| | Copper Foil Adhesion Strength (kN/m) | 0.4 | 0.5 | 0.5 |
| | Heat Resistance | GD | GD | GD |
| | Flame Retardance | V-0 | V-0 | V-0 |

Mw: Weight-average molecular weight
S.T.: Softening temperature
M.P.: Melting point

The results for Samples E1 to E18 shows that the use of the resin composition having the composition described in the embodiment allows the fabrication of the metal-clad laminates that feature the advantages of excellent dielectric characteristics, high accuracy in thickness, and excellent circuit filling properties.

In contrast, Sample C1 in which component (B) is smaller in molecular weight than component (A) shows lower accuracy in thickness. Sample C2 shows poorer circuit filling properties because of the higher softening temperature of component (B). Sample C3 shows lower accuracy in thickness because of the absent of component (B). Sample C4 shows insufficient curing of the resin composition because of the absent of component (C), resulting in insufficient dielectric characteristics, heat resistance, and adhesion of the copper foil. Sample C5 shows high dielectric characteristics compared to Samples E1 to E18. This is because Sample C5 uses the poly(phenylene ether) compound, as component (A), in which the terminal hydroxyl group is not modified, while Samples E1 to E18 uses the modified poly(phenylene ether) compounds in which the molecule terminals are modified with the substituent groups having carbon-carbon unsaturated double bonds.

Moreover, from the results of Samples E8 to E11 shown in Table 3, it can also be seen that the higher content of the inorganic filler results in an improvement in heat resistance, dielectric loss tangent, and CTE, but a decrease in adhesion and circuit filling properties.

Furthermore, the results of Samples E14 and E15 shows that the higher content of component (B) results in increased accuracy in thickness, but reduced heat resistance.

[Flame Retardance]

Moreover, Samples E16 to E18 are evaluated for their flame retardance.

For evaluating flame retardance, specimens are prepared by etching copper-clad laminate 2, and then cutting into rectangle pieces, each 127 mm×12.7 mm in size. The specimens are evaluated in accordance with UL 94. As shown in Table 4, the result from the evaluation shows that all of Samples E16 to E18 exhibit flame retardance evaluated to be V-0 grade. This means that the laminates of Samples E16 to E18 are excellent in flame retardance as well.

What is claimed is:

1. A poly(phenylene ether) resin composition comprising:
a modified poly(phenylene ether) copolymer in which a phenolic hydroxyl group in a molecular terminal of a poly(phenylene ether) copolymer is modified with a compound including a carbon-carbon unsaturated double bond;
a polymer substance having: a weight-average molecular weight larger than a weight-average molecular weight of the modified poly(phenylene ether) copolymer; a structure of at least one selected from a polystyrene framework, a polybutadiene framework, and a methacrylate framework; and a softening temperature not higher than 110° C.; and
a compound including two or more carbon-carbon unsaturated double-bonds per molecule, having a melting point not higher than 30° C., and being compatible with the modified poly(phenylene ether) copolymer.

2. The poly(phenylene ether) resin composition according to claim 1, wherein the weight-average molecular weight of the modified poly(phenylene ether) copolymer is in a range from 500 to 5000, inclusive.

3. The poly(phenylene ether) resin composition according to claim 1, wherein a substituent group expressed by Formula (A) is bonded to a terminal of the modified poly(phenylene ether), 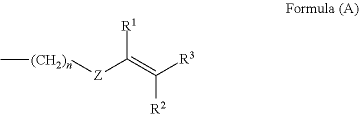
where “n” is an integer in a range from 0 (zero) to 10, inclusive, “Z” is one of an arylene group and a carbonyl group when n=0 (zero), “Z” is the arylene group when “n” is in a range from 1 (one) to 10, inclusive, and each of R¹ to R³ is independently one of a hydrogen atom and an alkyl group.

4. The poly(phenylene ether) resin composition according to claim 1, wherein the weight-average molecular weight of the polymer substance is in a range from 10,000 to 900,000, inclusive.

5. The poly(phenylene ether) resin composition according to claim 1, wherein the compound compatible with the modified poly(phenylene ether) copolymer is expressed by Formula (B), 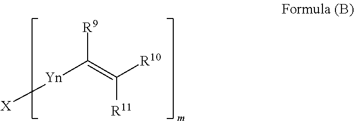
where “m” is an integer in a range from 1 (one) to 3, inclusive, “n” is one of 0 (zero) and 1 (one), each of R⁹ to R¹¹ is independently one of a hydrogen atom and an alkyl group, “X” is any one of an arylene group, a dicyclopentadienyl group, and an isocyanurate group, and “Y” is one of structures expressed by Formulas (C) and (D).

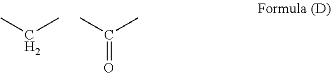

6. The poly(phenylene ether) resin composition according to claim 1, further comprising an inorganic filler.

7. The poly(phenylene ether) resin composition according to claim 6, wherein a content of the inorganic filler is in a range from 40 parts by mass to 250 parts by mass, inclusive, with respect to 100 parts by mass of a sum of contents of the modified poly(phenylene ether) copolymer, the polymer substance, and the compound compatible with the modified poly(phenylene ether) copolymer.

8. The poly(phenylene ether) resin composition according to claim 1, further comprising a phosphorus-based flame retardant.

9. The poly(phenylene ether) resin composition according to claim 8, wherein the phosphorus-based flame retardant is at least one selected from a phosphinate compound, a phosphoric ester compound, and a phosphazene compound.

10. Prepreg comprising:
a substrate; and
the poly(phenylene ether) resin composition according to claim 1 with which the substrate is impregnated.

11. A metal-clad laminate comprising:
an insulating layer being a cured product of the prepreg according to claim 10; and
metal foil disposed on the insulating layer.

12. A printed-wiring board comprising:
an insulating layer being a cured product of the prepreg according to claim 10; and
a conductive pattern disposed on the insulating layer.
